(19) United States
(12) Patent Application Publication
(10) Pub. No.: US 2002/0167911 A1
(43) Pub. Date: Nov. 14, 2002

(54) Method and apparatus for determining jitter buffer size in a voice over packet communications system

(75) Inventor: Joseph P. Hickey, Waterbury, CT (US)

Correspondence Address: David P. Gordon, Esq., 65 Woods End Road, Stamford, CT, 06905, US

(73) Assignee: Kenetec, Inc.

(21) Appl. No.: 10/053,318

(22) Filed: Jan. 18, 2002

Related U.S. Application Data
(60) Provisional application No. 60/276,630, filed on Mar. 16, 2001.

(51) Int. Cl. H04J 1/16; H04J 3/06

(52) U.S. Cl. 370/252; 370/516

(57) ABSTRACT

Methods of the invention include determining packet size by comparing the RTP timestamps of two consecutive packets, determining the expected (no jitter) local arrival time for the next packet by comparing the difference between the local clock and the timestamp of the present packet and summing it with the timestamp difference of the last two packets, and determining network jitter by comparing the expected local arrival time with the actual local arrival time. Computed network jitter are averaged to determine the average network jitter. The average network jitter is used to set the size of the dynamic buffer. An apparatus for performing the methods is also disclosed.

This application claims the benefit of co-owned, co-pending, provisional application serial No. 60/276,630 filed Mar. 16, 2001, entitled “Methods and Apparatus for Delivering Multimedia Communications Services to Multiple Tenants in a Building,” the complete disclosure of which is hereby incorporated by reference herein.

### BACKGROUND OF THE INVENTION

1. Field of the Invention

The invention relates to packet switching networks. More particularly, the invention relates to the transmission of voice signals over a packet network.

2. State of the Art

Before the advent of digital communications, voice telephone communications was accomplished by setting up a discrete physical circuit between the caller and the called party.

The first commercial digital voice communications system was installed in 1962 in Chicago, Ill. The system was called “T1” and was based on the time division multiplexing (TDM) of twenty-four telephone calls on two twisted wire pairs. The digital bit rate of the T1 system was 1.544 Mbit/sec (±200 bps), which was, in the nineteen sixties, about the highest data rate that could be supported by a twisted wire pair for a distance of approximately one mile. The cables carrying the T1 signals were buried underground and were accessible via manholes, which were, at that time in Chicago, spaced approximately one mile apart. Thus, analog amplifiers with digital repeaters were conveniently located at intervals of approximately one mile.

The T1 system is still widely used today and forms a basic building block for higher capacity communication systems including T3 which transports twenty-eight T1 signals. The designation T1 was originally coined to describe a particular type of carrier equipment. Today T1 is often used to refer to a carrier system, a data rate, and various multiplexing and framing conventions. While it is more accurate to use the designation “DS1” when referring to the multiplexed digital signal carried by the T1 carrier, the designations DS1 and T1 are often used interchangeably. Today, T1/DS1 systems still have a data rate of 1.544 Mbit/sec and support typically twenty-four voice and/or data DS0 channels. Similarly, the designations DS2 and T2 both refer to a system transporting up to four DS1 signals (96 DS0 channels) and the designations DS3 and T3 both refer to a system transporting up to seven DS2 signals (672 DS0 channels). The timing tolerance for modern T1 equipment has been raised to ±50 bps. T1 signals are said to be “plesiochronous” (nearly synchronous). Clock variations at nodes are corrected by line codes such as alternate mark inversion (AMI or bipolar line code). These codes set up patterns in the bitstream of the signal which are used at nodes to correct for clock variations.

Today, another higher bandwidth TDM system is in use. This system is referred to as the synchronous optical network (SONET) or, in Europe, the synchronous digital hierarchy (SDH). Unlike plesiochronous signals, SONET signals are synchronized to a master network clock. Although the timing of SONET signals is very accurate, some clock variations still exist at different nodes in the network. Various complex techniques are provided to correct for clock differences at different nodes.

The T1 and T3 networks were originally designed for digital voice communication. In a voice network minor bit errors can be tolerated as a small amount of noise. However, in a data network, a minor bit error cannot be tolerated. In the early 1970s, another technology was deployed to support data networks. The technology was called “packet switching”. Unlike the T1 and T3 networks, packet switching was designed for data communications only. In packet switching, a “packet” of data includes a header, a payload, and a cyclic redundancy check (CRC). The header includes addressing information as well as an indication of the length of the payload. The payload contains the actual data which is being transmitted over the network. The CRC is used for error detection. The receiver of the packet performs a calculation with the bits in the packet and compares the result of the calculation to the CRC value. If the CRC value is not the same as the result of the calculation, it means that the packet was damaged in transit. According to the packet switching scheme, the damaged packet is discarded and the receiver sends a message to the transmitter to resend the packet. One popular packet switching scheme for wide area networks (WANs), known as X.25, utilizes a packet which has a fixed payload of 128 octets. Other packet switching schemes allow variable length packets up to 2,000 octets. Frame Relay is an example of a WAN packet switching scheme which utilizes variable sized packets and Ethernet is an example of a local area network (LAN) packet switching scheme which utilizes variable sized packets. Packet switching networks are asynchronous and, by design, are not well suited for the transmission of a streaming signal such as voice or video. If streaming voice or video is transmitted via packets, small amounts of noise in the signal will result in discontinuity of the stream, echo, and other problems.

Concurrent with the development of packet switching several groups around the world began to consider standards for the interconnection of computer networks and coined the term “internetworking”. The leading pioneers in internetworking were the founders of ARPANET (the Advanced Research Projects Network). ARPA, a U.S. Department of Defense organization, developed and implemented the transmission control protocol (TCP) and the internet protocol (IP). The TCP/IP code was dedicated to the public domain and was rapidly adopted by universities, private companies, and research centers around the world. An important feature of IP is that it allows fragmentation operations, i.e. the segmentation of packets into smaller units. This is essential to allow networks which utilize large packets to be coupled to networks which utilize smaller packets. Today, TCP/IP is the foundation of the Internet. It is used for email, file transfer, and for browsing the Worldwide Web. It is so popular that many organizations are hoping to make it the worldwide network standard for all types of communication, including voice and video.

Perhaps the most awaited, and now fastest growing technology in the field of telecommunications is known as Asynchronous Transfer Mode (ATM) technology. ATM was originally conceived as a carrier of integrated traffic, e.g. voice, data, and video. ATM utilizes fixed length packets (called “cells”) of 53 octets (5 octets header and 48 octets payload). ATM may be implemented in either a LAN or a WAN. For ideal data transfer, ATM is used end to end from the data source to the data receiver.

Current ATM service is offered in different categories according to a user's needs. Some of these categories include constant bit rate (CBR), variable bit rate (VBR), unspecified bit rate (UBR), and available bit rate (ABR). CBR service is given a high priority and is used for streaming data such as voice and video where a loss of cells would cause a noticeable degradation of the stream and where retransmission of lost cells is pointless. UBR and ABR services are given a low priority and are used for data transfers such as email, file transfer, and web browsing where sudden loss of bandwidth (bursty bandwidth) can be tolerated and lost cells can be retransmitted beneficially. ATM service is sometimes referred to as “statistical multiplexing” as it attempts to free up bandwidth which is not needed by an idle connection for use by another, active, connection.

ATM switches (like other packet switches) typically include multiple (“jitter”) buffers, queues, or FIFOs for managing the flow of ATM cells through the switch. Generally, a separate buffer is provided for each outlet from the switch. However, it is also known to have separate buffers at the inlets to the switch. Buffer thresholds are set to prevent buffer overflow. If the number of cells in a buffer exceeds the threshold, no more cells are allowed to enter the buffer. Cells attempting to enter a buffer which has reached its threshold will be discarded.

Whenever streaming real time data such as voice or video is transmitted over a packet network, careful attention must be paid to the size of the jitter buffers in the packet switches. If the jitter buffer is too small, it can overflow resulting in the loss of data. In a voice over packet system, buffer overflow is usually perceived as an audible click or pop. If the jitter buffer is too large, the data will be subject to unnecessary delay.

There are two significant thresholds that are crossed as network delay increases. The first of these thresholds results from an electrical quirk of the world's telephone network. Telephone handsets use 4 wires to connect to the network. However, the network only uses a single pair of wires to carry a telephone call from a telephone to a central office. This transition from 2-wire to 4-wire operation is accomplished by the use of a device known as a “hybrid” in the telephones at each end of the network connection. Hybrids cause a reflection of signal, due to an unavoidable impedance mismatch. The effect of this is that some speech signal is reflected back toward the speaker by each hybrid. Normally this reflection is not noticed. However, if there is delay across the network, the reflected signal from the far-side hybrid will arrive back as an echo. The effect of this echo is more pronounced as the delay increases. At about 30 milliseconds of network delay, the echo is so significant as to make normal conversation very difficult. Therefore, once a voice circuit delay exceeds 30 milliseconds, echo cancelers must be included within the network. These devices are expensive and complex. Moreover, they operate most successfully when the delay over a circuit is constant, and this may not be the case in a packetized voice network.

Once in place echo cancellation systems allow network delays to reach approximately 150 milliseconds before further voice quality degradation is experienced. At about 150 milliseconds of delay a second problem emerges. At this level of delay, most people start to have significant problems in carrying on a normal conversation. Normal conversation patterns demand that some responses from the listener be received within less than 200 milliseconds, and delays of this order result in stilted conversations, and “clashing” (where both parties try to talk at once). This type of problem is commonly encountered over satellite links.

For these reasons toll quality networks require that the end to end network delay for voice traffic is less than 25 milliseconds in national networks and less than 100 milliseconds in an international context.

Buffering is not the only source of delay in a packet network. Delay also results from analog to digital conversion, packetization, and digital to analog conversion. Nevertheless, buffering must be given careful attention in order to maintain acceptable voice quality.

One of the difficulties in choosing buffer size in a packet network is that the jitter characteristics of the network vary over time depending on network usage. Current methods for determining the proper size of a jitter buffer consider the worst case scenario to compensate for network jitter during peak hours at the expense of introducing extra delay during non-peak hours.

The present Internet standard for transporting realtime streaming data such as voice and video is contained in RFC-1889 which was published in January 1996, the complete disclosure of which is hereby incorporated by reference herein. RFC-1889 describes the “real-time transport protocol” (RTP), which provides end-to-end delivery services for data with real-time characteristics, such as interactive audio and video. Those services include payload type identification, sequence numbering, timestamping, and delivery monitoring. Applications typically run RTP on top of UDP (user datagram protocol) to make use of UDP's multiplexing and checksum services. Both protocols contribute to the transport protocol functionality. However, RTP may be used with other suitable underlying network or transport protocols. RTP supports data transfer to multiple destinations using multicast distribution if available in the underlying network.

RTP itself does not provide any mechanism to ensure timely delivery of packets or provide any other quality-of-service guarantees, but relies on lower-layer services to do so. It does not guarantee delivery or prevent out-of-order delivery, nor does it assume that the underlying network is reliable and delivers packets in sequence. The sequence numbers included in RTP allow the receiver to reconstruct the sender's packet sequence, but sequence numbers might also be used to determine the proper location of a packet, for example in video decoding, without necessarily decoding packets in sequence.

### SUMMARY OF THE INVENTION

It is therefore an object of the invention to provide methods and apparatus for determining the proper size for jitter buffers in a voice over packet network.

It is also an object of the invention to provide methods and apparatus for determining the proper size for jitter buffers in a voice over packet network where the jitter characteristic of the network varies with time.

It is another object of the invention to provide methods and apparatus for determining the proper size for jitter buffers which does not allow undue delay during off-peak hours.

It is still another object of the invention to provide methods and apparatus for determining the proper size for jitter buffers such that the size of the buffers can be adjusted based on a quantitative measurement of actual network jitter.

In accord with these objects which will be discussed in detail below, the methods of the present invention are applicable to a packet switch which sends and receives RTP packets, has a local clock and an adjustable dynamic buffer, and where the size of the packets received is relatively constant. The methods of the invention include determining packet size by comparing the RTP timestamps of two consecutive packets, determining the expected (no jitter) local arrival time for the next packet by comparing the difference between the local clock and the timestamp of the present packet and summing it with the timestamp difference of the last two packets, and determining network jitter by comparing the expected local arrival time with the actual local arrival time. The absolute values of computed network jitter are averaged to determine the average network jitter. The average network jitter is used to set the size of the dynamic buffer. According to the presently preferred embodiment, large changes in jitter between consecutive packets are considered anomalies and are not used in the average jitter calculation. Conversely, only significant changes in the average jitter will call for a readjustment of the dynamic jitter buffer. When the buffer size is adjusted, audio traffic experiences an audible click or pop. However, the occasional click or pop is likely to be less annoying than undue delay. The methods of the invention can also be used in combination with a voice activity detector so that the buffer size adjustments are made less noticeable. That is, the buffer size is adjusted during a period of no voice activity.

Additional objects and advantages of the invention will become apparent to those skilled in the art upon reference to the detailed description taken in conjunction with the provided figures.

### BRIEF DESCRIPTION OF THE DRAWINGS

FIG. 1 is a simplified block diagram of an apparatus according to the invention; and

FIG. 2 is a simplified flow chart illustrating the methods of the invention.

### DETAILED DESCRIPTION OF THE PREFERRED EMBODIMENTS

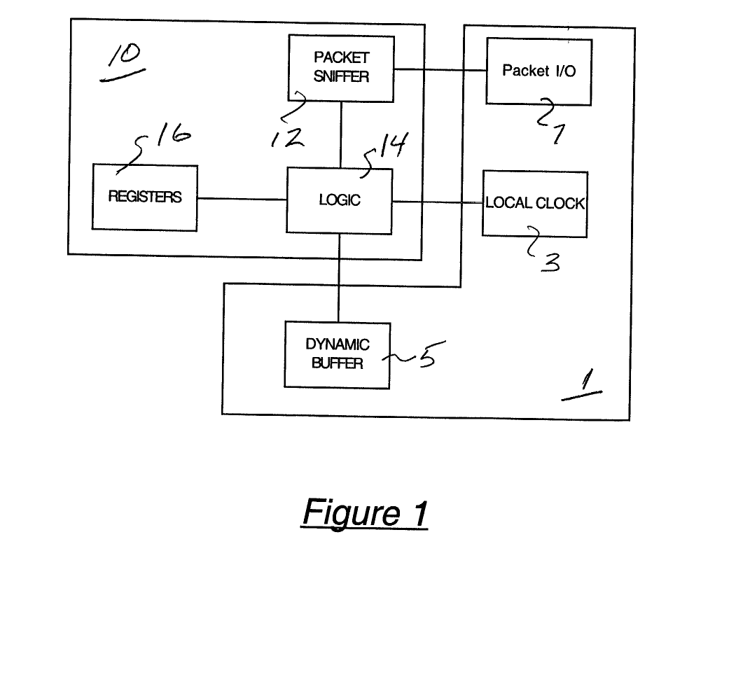

Referring now to FIG. 1, an apparatus 10 according to the invention is shown in conjunction with an RTP packet device 1 having a local clock 3, an adjustable dynamic buffer 5, and a packet I/O 7. The apparatus 10 includes a packet sniffer 12 coupled to the packet I/O 7 for reading the RTP headers of incoming packets, a logic block 14 for performing the methods of the invention, and a group of registers 16 for storing values of variables. The logic block 14 takes input from the packet sniffer 12 and the local clock 3, communicates bidirectionally with the registers 16, and provides an adjustment output to the dynamic buffer 5.

The invention utilizes the thirty-two bit timestamp which occupies bytes 4-7 of the RTP packet header. The timestamp reflects the time of the first sample in the packet payload based on the local clock of the transmitting device. The sample period for G.711 A-law/μ-law is always 125 μs (8000 hz). When the RTP device 1 is powered up, the timestamp is set to a random thirty-two bit value and is incremented by the local clock 3 until the device is shut down, wrapping to zero as the value overflows. The prior art devices only use the local clock to generate the timestamp in outgoing packets. The present invention uses the local clock and the timestamp on incoming packets to determine network jitter.

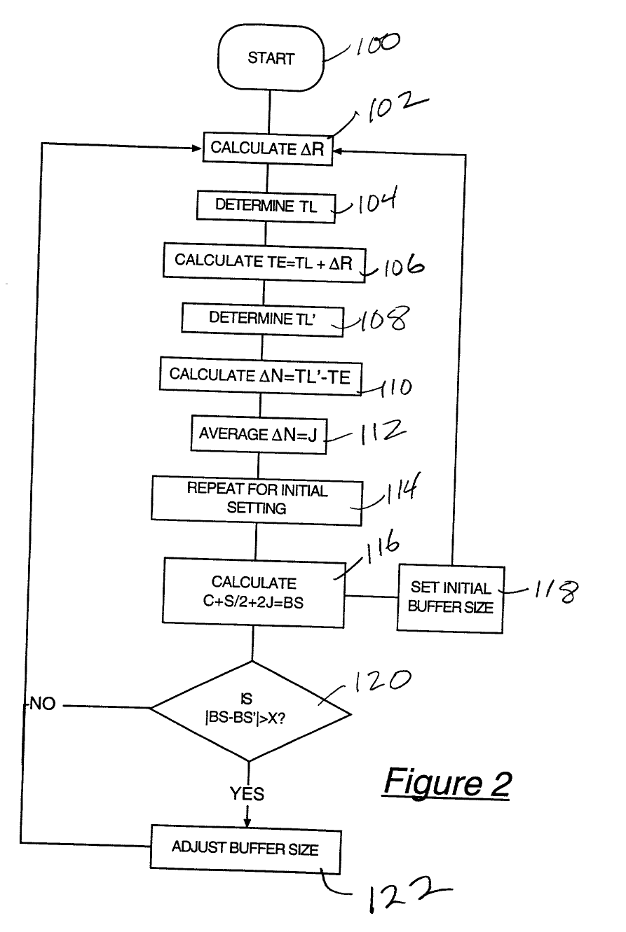

Turning now to FIG. 2, the methods of the invention are illustrated in a flow chart starting at 100. The first step in the method is to determine the length of the decompressed voice signal. It is not sufficient to simply look at the packet size because different voice coders will produce different packet sizes for the same amount of time. For example, ADPCM coding compresses 1 ms to 4 bytes, whereas μ-law coding compresses 1 ms to 8 bytes. By calculating the RTP timestamp difference (ΔR) between two consecutive packets, the expanded packet size (length of the decompressed voice signal) can be determined. No matter what compression system is used, the RTP timestamps are always based on an 8 KHz clock. Therefore, the difference ΔR is the duration in 125 μs periods. Thus, the first step shown in FIG. 2 is to calculate ΔR as indicated at 102. This value is stored in one of the registers (16 in FIG. 1). In a zero jitter network, the expected local arrival time of the next packet will be the local arrival time of the last packet plus ΔR. In order to calculate the expected local arrival time of the next packet in a zero jitter network, the local arrival time (TL) of the last packet is determined at 104 in FIG. 2. This value is also stored in one of the registers (16 in FIG. 1). The calculation of the expected local arrival time TE is illustrated at 106. The value TE is also stored in one of the registers (16 in FIG. 1). When the next packet arrives, it will arrive at an actual local time TL′ which, in a network with jitter, will be different from the expected time TE. The actual arrival time of the next packet is determined at 108 and this value TL′ is stored in one of the registers (16 in FIG. 1). The difference between the actual arrival time TL′ and the expected arrival time TE is calculated at 110 and the difference ΔN is considered an indication of network jitter. The absolute value of ΔN is stored in another one of the registers (preferably an accumulator). A count of the number of ΔNs accumulated is stored in another register. The average value of the accumulated ΔNs is calculated at 112 and the result J is stored in a register. Before proceeding to set the initial buffer size, steps 102-112 are repeated for several hundred packets. For example, a loop counter at 114 causes the calculation of J to be updated until it is based on an average of several hundred packet arrivals.

The buffer size is calculated at 116. According to the presently preferred embodiment, the buffer size BS is calculated according to the formula BS=C+(S/2)+2J where C is the minimum size of a buffer in a zero jitter network, S is the size of the packets, and J is the average network jitter as described above. The buffer size BS is initially set at 118 and the method continues at 102 through 112 to recalculate J based on the jitter detected in the next received packet. According to the presently preferred embodiment, if the calculation at 110 produces a ΔN which differs greatly (e.g. by a packet size or more) from the last calculated ΔN, the calculation is ignored. After the new buffer size BS′ is calculated at 116, it is compared at 120 to the present buffer size BS. If the difference is insignificant (e.g. less than 8 ms), no change is made in the buffer size and the method returns to 102. If the difference is substantial (e.g. more than 8 ms), the buffer size is adjusted at 122 and the process proceeds at 102 through continuing cycles.

In the presently preferred implementation, the methods of the invention are separated into a foreground task and a background task. The foreground task calculates J and the background task updates the buffer size. Thus, in the Flow chart, the steps 118, 120, and 122 are run in a separate timed loop. Exemplary source code for the foreground task is illustrated in the code listing below which is separately line numbered for easy reference.

; Detect Jitter
;
; don't detect jitter until channel has reached a steady state

condition

| rsbx SXM | |
|---|---|
| ldm | T, B |
| stlm | B, AR4 |

| | |
|---|---|
| mpy | #HEADER_SIZE, B |
| add | #_chnl_header, B |

| | |
|---|---|
| stlm | B, AR2 |

| ld | *AR4(_chnl_state), B | |
|---|---|---|
| and | #RX_ON_MASK, B | ; Once spigot is |

turned on, channel is in OK state

| bc | UpdNPTime, BEQ |
|---|---|
| ; Channel is (hopefully) in a steady State condition | |
| ; Compare Actual & Expected Arrival Times | |
| dld | *AR3 (_LastPacketLTime), B |

; Get Local Sample Time
; load recieved (remote) rtp timestamp into acc. A.
; This must be done as two loads because it may not be aligned

for dld

| | |
|---|---|
| ld *AR2 (LOCALSTAMP−1) 16, A | ; load high word |
| OR *AR2 (LOCALSTAMP), A | ; load low word |

| ; | | |
|---|---|---|
| ; B = predicted time time, A = actual time | | |
| ; | | |
| ssbx SXM | | |
| nop | | |
| ;xc | 2, TC | |
| ;stm | #Offh, AG | ; correct AG for sign bit. |

| | |
|---|---|
| sub | A, B |

| | |
|---|---|
| abs | B |

| | | |
|---|---|---|
| sub | #1000, B, A | ; If we have a huge difference, ignore it. |
| bc | UpdNPTime, AGT | |

| | | |
|---|---|---|
| dadd | *AR3(_AvgTimeDiff), B | ; add to the time diff's |

| | |
|---|---|
| dst | B, *AR3(_AvgTimeDiff) |

UpdNPTime:

| | |
|---|---|
| ;Update | “Next Packet” Expected Arrival Time |
| mvdk | *AR1 (UDP_HEADER_SIZE+RTP_TIMESTAMP_OFFSET−1), BH |
| mvdk | *AR1 (UDP_HEADER_SIZE+RTP_TIMESTAMP_OFFSET), BL |
| ld | B, A |
| dsub | *AR3 (_LastPacketRTime), B |

| | |
|---|---|
| st | #0, *(BG) |

| | |
|---|---|
| dst | A, *AR3(_LastpacketRTime) |
| mvdk | |

*AR2 (ETHER_HEADER_SIZE+IP_HEADER_SIZE+UDP_{—}
HEADER_SIZE+RTP_TIMESTAMP_OFFSET−1),AH

mvdk

*AR2 (ETHER_HEADER_SIZE+IP_HEADER_SIZE+UDP_{—}
HEADER_SIZE+RTP_TIMESTAMP_OFFSET),AL

| nop | |
|---|---|
| add | A, B |

| | |
|---|---|
| dst | B, *AR3(_LastPacketLTime) |

Lines 1-18 of the code listing determine whether the channel is in a steady enough state to begin calculating jitter. At lines 19 and 20, the actual and expected arrival times are compared. The local sample time is obtained at lines 21-44. The next packet expected arrival time is then updated at lines 46-60 and the process is repeated as described above with reference to FIG. 2.

Exemplary source code for the foreground task is illustrated in the code listing below which is separately line numbered for easy reference.

case RING_CADENCE:
RingCadence++;
if (RingCadence >= 3)
RingCadence = 0;
writeFlag = 1;
msg [0] = HEARTBEAT;
msg [1] = = 0×FF;
/* Use this opportunity to adjust jitter

buffers for optimum quality */

/* AvgTimeDiff is sum of absolute value

of *sample* time diffs */

for (line = 0; line <

NUMBER_OF_CHANNELS; line++)

if ((OctetsSent [line] > 32000)

&& ((chnl_state [line] >> RX_SHIFT) & STATE_MASK) == ACTIVE_STATE)

{
if (CrashCount [line] >

0×100)

CrashCount [line]

= 0×100;

temp =

(AvgTimeDiff [line] / PacketsSent [line]) + (DataRate [line] >> 3) + 2 +
(AvgPacktRecvd [line] >>1) + (CrashCount [line] <<3);

if (temp > 0×180)
temp = 0×180;
if (abs(temp −

OptimalJBLevel [line]) > 32)
OptimalJBLevel [line] = temp;

if (CrashCount [line] > 0)

CrashCount [line]--;

}
break;

The cycle time for resetting the buffer size is set at lines 1-7 using the variables RING_CADENCE and HEARTBEAT. The average time difference is determined at lines 8-20. A possible new buffer size is calculated at lines 21-25. At lines 26-27, it is determined whether the difference between the old buffer size and the new buffer size is more than 32 words. If it is, the new buffer size is used to adjust the buffer. CrashCount is used to increase the minimum buffer size every time the buffer crashes so as to attempt to prevent another crash.

There have been described and illustrated herein methods and apparatus for determining jitter buffer size and adjusting a dynamic buffer accordingly in a voice over packet communications system. While particular embodiments of the invention have been described, it is not intended that the invention be limited thereto, as it is intended that the invention be as broad in scope as the art will allow and that the specification be read likewise. It will therefore be appreciated by those skilled in the art that yet other modifications could be made to the provided invention without deviating from its spirit and scope as so claimed.

1. A method for determining jitter buffer size in a voice over packet communications system, comprising:
a) comparing the RTP timestamps of two consecutive packets;
b) determining the expected arrival time for the next packet based on said step of comparing;
c) determining network jitter by comparing the expected arrival time for the next packet with the actual arrival time for the next packet; and
d) calculating jitter buffer size based on the determined network jitter.

2. A method according to claim 1, wherein:
said step of determining the expected arrival time includes comparing the difference between the local clock and the timestamp of the present packet and summing it with the timestamp difference of the last two packets.

3. A method according to claim 1, further comprising:
e) repeating steps a) through c);
f) determining the average network jitter; and
g) recalculating jitter buffer size based on the determined average network jitter.

4. A method according to claim 1, wherein:
said step of calculating jitter buffer size includes calculating the formula BS=C+S/2+2J where BS is the jitter buffer size, C is the minimum size of a buffer in a zero jitter network, S is the size of the packets, and J is the network jitter.

5. A method according to claim 3, wherein:
said step of recalculating jitter buffer size includes calculating the formula BS=C+S/2+2J where BS is the jitter buffer size, C is the minimum size of a buffer in a zero jitter network, S is the size of the packets, and J is the average network jitter.

6. A method for adjusting jitter buffer size in a voice over packet communications system, comprising:
a) comparing the RTP timestamps of two consecutive packets;
b) determining the expected arrival time for the next packet based on said step of comparing;
c) determining network jitter by comparing the expected arrival time for the next packet with the actual arrival time for the next packet;
d) calculating jitter buffer size based on the determined network jitter; and
e) adjusting the size of the jitter buffer to the calculated jitter buffer size.

7. A method according to claim 6, wherein:
said step of determining the expected arrival time includes comparing the difference between the local clock and the timestamp of the present packet and summing it with the timestamp difference of the last two packets.

8. A method according to claim 6, further comprising:
f) repeating steps a) through c)];
g) determining the average network jitter;
h) recalculating jitter buffer size based on the determined average network jitter; and
i) readjusting the size of the jitter buffer to the recalculated jitter buffer size.

9. A method according to claim 8, wherein:
if network jitter determined in step c) is approximately one packet length or more, it is not included in the average determined at step g).

10. A method according to claim 8, wherein:
step i) is not performed if the buffer size found in step h) is less than 8 ms different from the buffer size determined in step d)

11. A method according to claim 6, wherein:
said step of calculating jitter buffer size includes calculating the formula BS=C+S/2+2J where BS is the jitter buffer size, C is the minimum size of a buffer in a zero jitter network, S is the size of the packets, and J is the network jitter.

12. A method according to claim 8, wherein:
said step of recalculating jitter buffer size includes calculating the formula BS=C+S/2+2J where BS is the jitter buffer size, C is the minimum size of a buffer in a zero jitter network, S is the size of the packets, and J is the average network jitter.

13. An apparatus for determining jitter buffer size in a voice over packet communications system, comprising:
a) first comparison means for comparing the RTP timestamps of two consecutive packets;
b) first determining means coupled to said first comparison means for determining the expected arrival time for the next packet;
c) second comparison means coupled to said first determining means for comparing the expected arrival time for the next packet with the actual arrival time for the next packet; and
d) calculating means coupled to said second comparison means for calculating jitter buffer size.

14. An apparatus according to claim 13, wherein:
said first determining means includes means for comparing the difference between the local clock and the timestamp of the present packet and summing it with the timestamp difference of the last two packets.

15. An apparatus according to claim 13, further comprising:
e) averaging means coupled to said second comparison means for determining the average network jitter, wherein
said calculating means includes recalculating means for recalculating jitter buffer size based on the average network jitter.

16. An apparatus according to claim 13, wherein:
said calculating means includes means for calculating the formula BS=c+S/2+2J where BS is the jitter buffer size, C is the minimum size of a buffer in a zero jitter network, S is the size of the packets, and J is the network jitter.

17. An apparatus according to claim 15, wherein:
said recalculating means includes means for calculating the formula BS=C+S/2+2J where BS is the jitter buffer size, C is the minimum size of a buffer in a zero jitter network, S is the size of the packets, and J is the average network jitter.

18. An apparatus for adjusting jitter buffer size in a voice over packet communications system, comprising:
a) first comparison means for comparing the RTP timestamps of two consecutive packets;
b) first determining means coupled to said first comparison means for determining the expected arrival time for the next packet;
c) second comparison means coupled to said first determining means for comparing the expected arrival time for the next packet with the actual arrival time for the next packet;
d) calculating means coupled to said second comparison means for calculating jitter buffer size; and
e) adjusting means coupled to said calculating means for adjusting the size of the jitter buffer.

19. An apparatus according to claim 18, wherein:
said first determining means includes means for comparing the difference between the local clock and the timestamp of the present packet and summing it with the timestamp difference of the last two packets.

20. An apparatus according to claim 18, further comprising:
f) averaging means coupled to said second comparison means for determining the average network jitter, wherein
said calculating means includes recalculating means for recalculating jitter buffer size based on the average network jitter, and
said adjusting means includes means for readjusting the size of the jitter buffer.

21. An apparatus according to claim 20, wherein:
said averaging means excludes differences of one packet size or more in calculating averages.

22. An apparatus according to claim 20, wherein:
said means for readjusting does not readjust the size of the jitter buffer is said recalculating means recalculates a buffer size which differes less than 8ms from the present buffer size.

23. An apparatus according to claim 18, wherein:
said calculating means includes means for calculating the formula BS=C+S/2+2J where BS is the jitter buffer size, C is the minimum size of a buffer in a zero jitter network, S is the size of the packets, and J is the network jitter.

24. An apparatus according to claim 20, wherein:
said recalculating means for calculating the formula BS=C+S/2+2J where BS is the jitter buffer size, C is the minimum size of a buffer in a zero jitter network, S is the size of the packets, and J is the average network jitter.
